(19) United States
(12) Patent Application Publication
(10) Pub. No.: US 2021/0175383 A1
(43) Pub. Date: Jun. 10, 2021

(54) SOLAR CELL DEVICE AND METHOD FOR MANUFACTURING SOLAR CELL DEVICE

(71) Applicant: KANEKA CORPORATION, Osaka-shi, Osaka (JP)

(72) Inventors: Kunta YOSHIKAWA, Settsu-shi (JP); Shinya OMOTO, Settsu-shi (JP); Yuji TAKAHASHI, Settsu-shi (JP)

(21) Appl. No.: 17/048,945

(22) PCT Filed: Apr. 1, 2019
(86) PCT No.: PCT/JP2019/014454

§ 371 Date: Oct. 19, 2020

(30) Foreign Application Priority Data
Apr. 19, 2018 (JP) 2018-080906

(51) Int. Cl. H01L 31/05; H01L 31/0224; H01L 31/048; H01L 31/18

(52) U.S. Cl. CPC H01L 31/0508; H01L 31/18; H01L 31/0488; H01L 31/022425

(57) ABSTRACT

In a solar cell device, adjacent solar cells are connected such that one of the adjacent solar cells overlaps with the other while having a connection member interposed therebetween. In the solar cell, a region in an end portion overlaid by the adjacent solar cell is referred to as an overlapping region, a region in the overlapping region which is in contact with the connection member is referred to as a connection region, and a region in the overlapping region which surrounds the connection region is referred to as a surrounding region. In the solar cell, outside the overlapping region, a surface of the metal electrode layer is covered with an oxide film, and the surface of the metal electrode layer in the connection region and a portion of the surface of the metal electrode layer in the surrounding region are not covered with an oxide film.

### TECHNICAL FIELD

The present invention relates to a solar cell device and a method for manufacturing such a solar cell device.

### BACKGROUND ART

Recently, there is a method for modularizing double-sided electrode type solar cells, according to which method, the solar cells are arranged to overlap with each other, whereby an electrical and physical direct connection is established without using any conductive connection wire. This connection method is referred to as a shingling method. A plurality of double-sided electrode type solar cells that are electrically connected together by the shingling method is referred to as a solar cell string (solar cell device) (see, for example, Patent Document 1).

Adoption of the solar cell string (solar cell device) makes it possible to mount an increased number of solar cells in a limited solar cell-mounting area of a solar cell module, thereby increasing a light-receiving area for photoelectric conversion and enhancing an output of the solar cell module. Further, the solar cell string (solar cell device) has an overlapping region where adjacent ones of the solar cells overlap with each other. In the overlapping region, since a bus bar electrode of one solar cell is covered by the other solar cell, a light shield loss due to the bus bar electrode is reduced, whereby the output of the solar cell module is enhanced.

Patent Document 1: Japanese Unexamined Patent Application, Publication No. 2017-517145

Patent Document 2: Japanese Unexamined Patent Application, Publication No. H10-313126

### DISCLOSURE OF THE INVENTION

### Problems to be Solved by the Invention

According to the solar cell string (solar cell device), while the bus bar electrode of one solar cell is covered with the adjacent solar cell, finger electrodes are exposed so that they are visually recognized as a stripe pattern which is undesirable for design characteristics. To address this, Patent Document 2 discloses a technique to blacken a surface of a light-receiving surface electrode made of a metal, such as silver, by way of oxidization of the surface. This technique can make the light-receiving surface electrode be the same color as the other portion of the light-receiving surface.

However, application of the technique disclosed in Patent Document 2 to a solar cell string (solar cell device) is considered to cause an increase in contact resistance of electrical connection parts when the plurality of double-sided electrode type solar cells are electrically connected, and consequently, to result in a decrease in the output of the solar cell string (solar cell device).

An object of the present invention is to provide a solar cell device which is excellent in design characteristics, while inhibiting a decrease in the output of the solar cell device.

### Means for Solving the Problems

A solar cell device according to the present invention includes a plurality of double-sided electrode type solar cells having both major surfaces provided with metal electrode layers, the solar cells being electrically connected to each other by a shingling method. Adjacent ones of the solar cells are electrically connected to each other such that one of the adjacent solar cells overlaps with the other while having a connection member interposed therebetween. In the solar cell, a region which is located in an end portion overlaid by the adjacent solar cell, and which is on one of the major surfaces facing the adjacent solar cell is referred to as an overlapping region, a region which is included in the overlapping region and is in contact with the connection member is referred to as a connection region, and a region which is included in the overlapping region and surrounds the connection region is referred to as a surrounding region. Outside the overlapping region of the solar cell, a surface of the metal electrode layer on at least one major surface of the major surfaces is covered with an oxide film, and the surface of the metal electrode layer in the connection region of the solar cell and at least a portion of the surface of the metal electrode layer in the surrounding region of the solar cell are not covered with an oxide film.

A method according to the present invention is for manufacturing a solar cell device including a plurality of double-sided electrode type solar cells having both major surfaces provided with metal electrode layers, the solar cells being electrically connected to each other by a shingling method. In the solar cell, a region which is located in an end portion overlaid by the adjacent solar cell, and which is on one of the major surfaces facing the adjacent solar cell is referred to as an overlapping region, a region which is included in the overlapping region and is in contact with the connection member is referred to as a connection region, and a region which is included in the overlapping region and surrounds the connection region is referred to as a surrounding region. The method includes: forming an oxidation resistant film on a surface of the metal electrode layer in the overlapping region of the solar cell; and forming, by way of exposure to an oxidative atmosphere, an oxide film on the surface of the metal electrode layer on at least one of the major surfaces, the surface being located outside the overlapping region of the solar cell. The forming the oxidation resistant film includes forming, before the connection member is arranged in the connection region of the solar cell, the oxidation resistant film on the surface of the metal electrode layer in the connection region of the solar cell and at least a portion of the surface of the metal electrode layer in the surrounding region, or forming, after the connection member is arranged in the connection region of the solar cell, the oxidation resistant film on at least a portion of the surface of the metal electrode layer in the surrounding region.

### Effects of the Invention

The present invention provides a solar cell device which is excellent in design characteristics, while inhibiting a decrease in the output of the solar cell device.

### BRIEF DESCRIPTION OF THE DRAWINGS

FIG. 1 is diagram showing a solar cell module as viewed from a light-receiving surface side, the solar cell module including a solar cell device according to a first embodiment:

FIG. 2 is a cross-sectional view taken along line II-II in FIG. 1;

FIG. 3 is a diagram showing a solar cell according to the first embodiment, as viewed from the light-receiving surface side;

FIG. 4 is a diagram showing the solar cell according to the first embodiment, as viewed from a back surface side;

FIG. 5 is a cross-sectional view taken along line V-V in FIGS. 3 and 4;

FIG. 6 is a cross-sectional view taken along line VI-VI in FIGS. 3 and 4;

FIG. 7 shows an enlarged view of an overlapping region and a vicinity thereof in the cross section taken along line II-II in FIG. 1;

FIG. 8 shows an enlarged view of the overlapping region and a vicinity thereof in the cross section taken along line VIII-VIII in FIG. 1;

FIG. 9A is a diagram showing a barrier film forming step included in a method for manufacturing the solar cell device according to the first embodiment;

FIG. 9B is a diagram showing an oxide film forming step included in the method for manufacturing the solar cell device according to the first embodiment;

FIG. 9C is a diagram (cross-sectional view) showing a connecting and baking step included in the method for manufacturing the solar cell device according to the first embodiment;

FIG. 10 is a diagram for explaining the connecting and baking step shown in FIG. 9C;

FIG. 11 shows an enlarged view of an overlapping region and a vicinity thereof of a solar cell device according to a second embodiment, in a cross section taken along line II-II in FIG. 1;

FIG. 12 shows an enlarged view of the overlapping region and a vicinity thereof of the solar cell device according to the second embodiment, in the cross section taken along line VIII-III in FIG. 1;

FIG. 13A is a diagram showing a connecting step included in a method for manufacturing the solar cell device according to the second embodiment;

FIG. 13B is a diagram showing a baking and barrier film forming step included in the method for manufacturing the solar cell device according to the second embodiment;

FIG. 13C is a diagram showing an oxide film forming step included in the method for manufacturing the solar cell device according to the second embodiment;

FIG. 14A shows an enlarged view of an overlapping region and a vicinity thereof in a cross section of a solar cell device according to a modification of the second embodiment, the cross section corresponding to the cross section taken along line VIII-VIII in FIG. 1; and

FIG. 14B shows an enlarged view of an overlapping region and a vicinity thereof in a cross section of a solar cell device according to a modification of the second embodiment, the cross section corresponding to the cross section taken along line VIII-VIII in FIG. 1.

### PREFERRED MODE FOR CARRYING OUT THE INVENTION

An embodiment of the present invention will be described below. It should be noted that the present invention is not limited to the following embodiment. For the sake of convenience, hatching, reference characters denoting components, and the like may be omitted from a drawing. In such a case, reference shall be made to another drawing. Note that for the sake of convenience, the dimensions of various components are adjusted in the drawings for ease of viewing.

### First Embodiment

(Solar Cell Module)

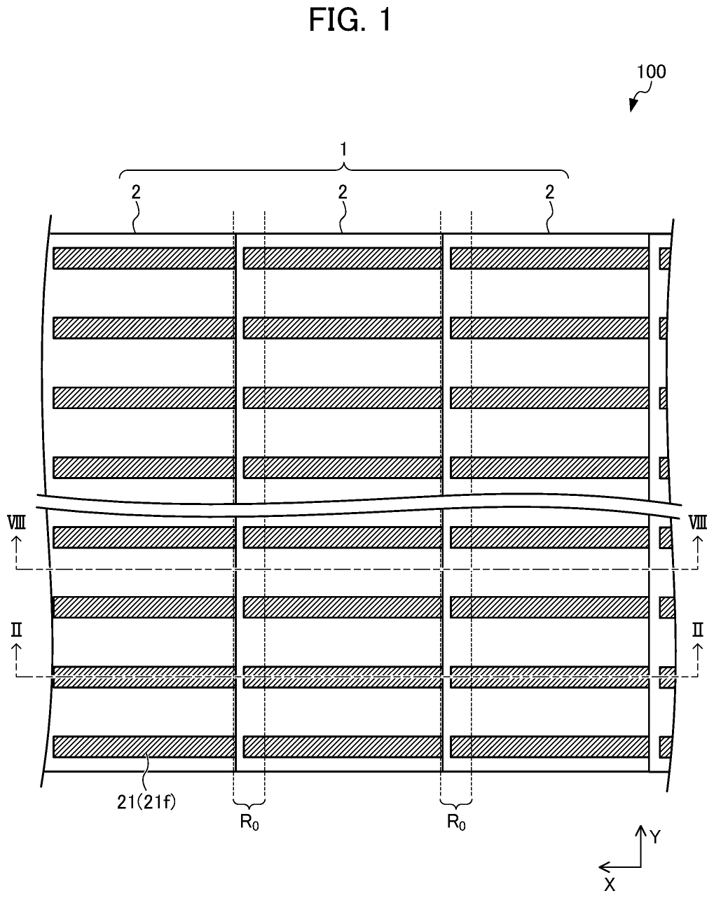

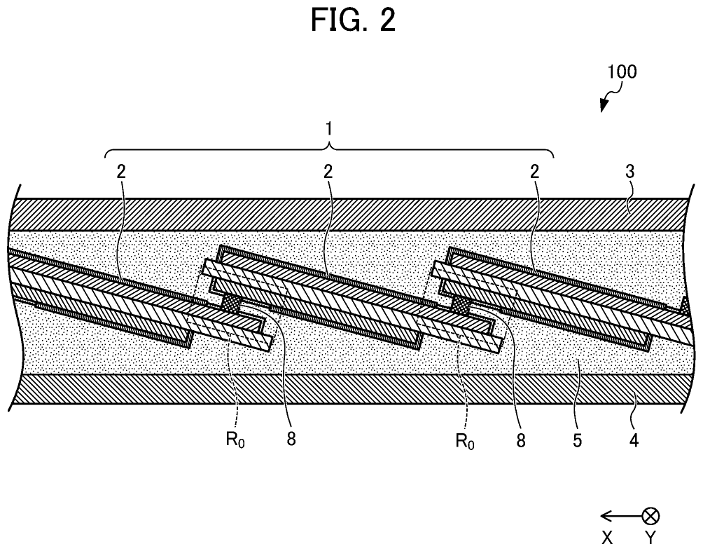

FIG. 1 is diagram showing a solar cell module including a solar cell device according to a first embodiment, as viewed from a light-receiving surface side. FIG. 2 is a cross-sectional view taken along line II-II in FIG. 1. As shown in FIGS. 1 and 2, the solar cell module 100 includes at least one solar cell device 1 (also referred to as the solar cell string 1) that is composed of at least two rectangular solar cells 2 of the double-side electrode type that are electrically connected to each other by the shingling method.

The solar cell device 1 is sandwiched between a light-receiving side protective member 3 and a backside protective member 4. A space between the light-receiving side protective member 3 and the backside protective member 4 is filled with a sealing material 5 in a liquid or solid form, whereby the solar cell device 1 is sealed.

The sealing material 5 is intended to seal and protect the solar cell device 1, i.e., the solar cells 2. The sealing material 5 is interposed between the light-receiving side protective member 3 and surfaces of the solar cells 2 facing the light-receiving side, and between the backside protective member 4 and surfaces of the solar cells 2 facing the backside. The sealing material 5 may have any shape or form, examples of which include a sheet shape. This is because the sheet shape facilitates covering the front and back surfaces of the solar cells 2. Although a material for the sealing material 5 is not particularly limited, it is preferable that the material has a property of transmitting light (translucency). In addition, the material for the sealing material 5 preferably has adhesive properties that allow the solar cells 2, the light-receiving side protective member 3, and the backside protective member 4 to adhere to one another. Examples of materials with such properties include a light transmissive resin such as an ethylene/vinyl acetate copolymer (EVA), an ethylene/α-olefin copolymer, ethylene/vinyl acetate/triallyl isocyanurate (EVAT), polyvinyl butyrate (PVB), an acrylic resin, a urethane resin, and a silicone resin.

The light-receiving side protective member 3 covers a surface (light-receiving surface) of the solar cell device 1, i.e., of the solar cells 2 with the interposition of the sealing material 5, and protects the solar cells 2. Although the light-receiving side protective member 3 may have any shape, a plate shape or a sheet shape is preferable from the viewpoint of indirectly covering the planar light-receiving surface. The material for the light-receiving side protective member 3 is not particularly limited, but it is preferable to use a material that is resistant to ultraviolet light while having light transmissive properties, similarly to the sealing material 5. Examples of materials include glass and a transparent resin such as an acrylic resin and a polycarbonate resin. The surface of the light-receiving side protective member 3 may be processed to have depressions and protrusions, or may be covered with an antireflection coating layer. Such processing or coating makes the light-receiving side protective member 3 less likely to reflect light received thereon, and thus, allows more light to be guided to the solar cell device 1.

The backside protective member 4 covers the back surface of the solar cell device 1, i.e., of the solar cells 2 with the interposition of the sealing material 5, and protects the solar cells 2. Although the backside protective member 4 may have any shape, similarly to the light-receiving side protective member 3, a plate shape or a sheet shape is preferable from the viewpoint of indirectly covering the planar back surface. The material for the backside protective member 4 is not particularly limited, but a material that prevents the infiltration of water or the like (having high water impermeability) is preferable. Examples of materials include a laminated structure of a resin film of polyethylene terephthalate (PET), polyethylene (PE), an olefin-based resin, a fluorine-containing resin, a silicone-containing resin, or the like, and metal foil such as aluminum foil.

(Solar Cell Device)

The solar cell device 1 includes the solar cells 2 arranged to overlap with each other while having parts of their end portions overlaid one above the other, so as to be connected in series. Specifically, referring to the solar cells 2, 2 that are adjacent to each other, a part of one surface (e.g., the light-receiving surface) of one solar cell 2 is overlaid by a part of the opposite surface (e.g., the back surface) of the other solar cell 2, the former part being located in an end portion of the one cell 2 in an X direction and the latter part being located in the opposite end portion of the other cell 2 in the X direction. Each solar cell 2 has bus bar electrode portions (to be described later) which are formed respectively on the part of the light-receiving surface of one end portion and on the part of the back surface of the other end portion, and which extend in a Y direction. The bus bar electrode portion on the light-receiving surface in one end portion of one solar cell 2 are electrically connected, via a connection member 8, for example, to the bus bar electrode portion on the back surface in the other end portion of the other solar cell 2. As can be seen, an imbricate structure is formed in which the plurality of solar cells 2 are arranged to overlap with each other and to be uniformly inclined in a certain direction, like a tiled roof. For this reason, the method by which the solar cells 2 are electrically connected as described above is called the shingling method. The plurality of solar cells 2 connected into the shape of a string is referred to as a solar cell string (solar cell device). In the following description, in each solar cell 2, a region that is located in the end portion overlaid by the adjacent solar cell 2, and that is on one of the major surfaces facing the adjacent solar cell 2 is referred to as an overlapping region Ro.

As the connection member 8 of the first embodiment, a ribbon wire composed of a copper core coated with a low melting point metal, a conductive film composed of a thermosetting resin film encapsulating therein fine particles of a low melting point metal, or a conductive adhesive composed of fine particles of a low melting point metal and a binder is usable, for example.

Both ends of the solar cell device 1 are connected to wiring members (not shown) used for external wiring to the outside of the solar cell device 1 or electrical connection to another solar cell string. Generally, metal foil or a lead wire including a core of copper coated with a low melting point metal is used as the wiring member. The details of the solar cell device 1 will be described later. The solar cell 2 included in the solar cell device 1 will be described below.

(Solar Cell)

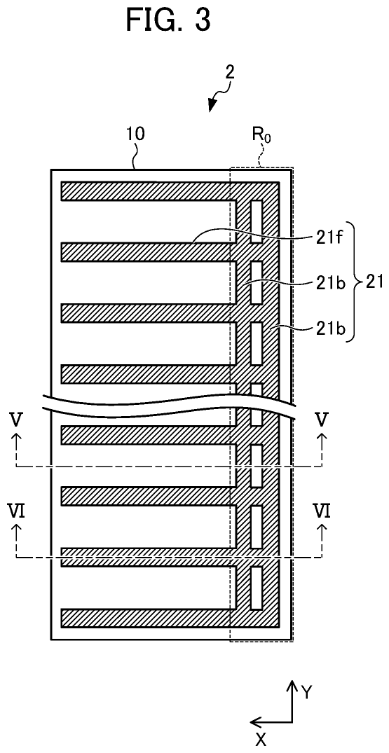

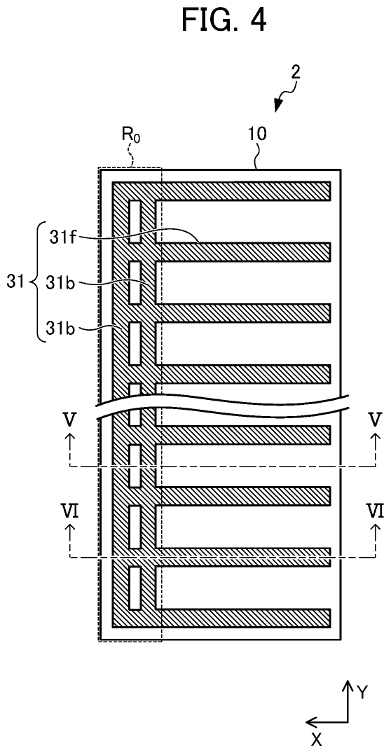

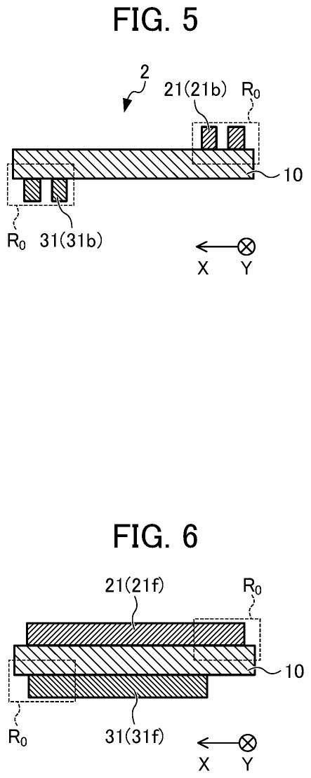

FIG. 3 is a diagram showing the solar cell 2 according to the first embodiment, as viewed from the light-receiving surface side. FIG. 4 is a diagram showing the solar cell 2 according to the first embodiment, as viewed from the back surface side. FIG. 5 is a cross-sectional view taken along line V-V in FIGS. 3 and 4. FIG. 6 is a cross-sectional view taken along line VI-VI in FIGS. 3 and 4. The solar cell 2 shown in FIGS. 3 to 6 is a double-sided electrode type solar cell having a rectangular shape. The solar cell 2 includes: a solar cell substrate 10 having two major surfaces; a metal electrode layer 21 formed on one of the major surfaces (e.g., the light-receiving surface side) of the solar cell substrate 10; and a metal electrode layer 31 formed on the other one of the major surfaces (e.g., the back surface side) of the solar cell substrate 10.

The solar cell substrate 10 includes a polycrystalline silicon substate or a monocrystalline silicon substrate. On a surface of the silicon substrate, a pn junction is formed to collect carriers generated by light irradiation. The pn junction is formed by way of formation of an emitter layer doped with a conductive dopant of a conductivity that is opposite to the conductivity of the silicon substrate. The emitter layer may be formed in a thickness region of several micrometers from the surface of the crystalline silicon substrate by way of thermal diffusion. Alternatively, an amorphous silicon layer or the like having a thickness of about 5 nm or more and about 20 nm or less may be produced to serve as the emitter layer on the surface of the crystalline silicon substrate.

In general, a junction mode by which the emitter layer is formed in a crystalline silicon substrate by way of diffusion is called homojunction, whereas a junction mode by which the emitter layer is formed by way of production of a thin film layer having a different band gap on a surface of a crystalline silicon substrate is called heterojunction. If a crystalline silicon substrate has p-type conductivity, electrons are the minority carriers, and are collected from an n-type emitter layer. On the other hand, if a crystalline silicon substrate has n-type conductivity, holes are the minority carriers, and are collected from a p-type emitter layer.

Generally, in the case of a double-sided electrode type solar cell, an emitter layer is formed on one of the major surfaces of the crystalline silicon substrate and a base layer for collecting the majority carriers is formed on the other of the major surfaces. The base layer bears a charge that is opposite to the charge of the emitter layer so that the base layer attracts the majority carriers to the surface of the silicon substrate and make the minority carriers return toward the inside of the substrate. In other words, the base layer has the same conductivity type as that of the crystalline silicon substrate, and retains electric charge at a higher concentration. The base layer may be formed by way of diffusion of dopants, or by way of alloying aluminum (Al) or the like with silicon such that a similar electric field is formed. Alternatively, a doped thin film may be formed on a surface of the crystalline silicon substrate.

In both of the case of homojunction and the case of heterojunction, a passivation layer for chemically terminating defect levels of both major surfaces of the crystalline silicon substrate is important for inhibiting recombination of the carriers. In the case of homojunction, the surface of the emitter layer or the surface of the base layer constitutes the surface of the crystalline silicone substrate, the layers both having been formed by way of diffusion or the like. Therefore, a passivation layer composed of a thermal oxide film, silicon nitride, or a laminated structure thereof is formed on the emitter layer. For the base side, if the base layer is formed by way of diffusion, a passivation layer is formed on the surface of the base layer (the surface of the crystalline silicon substrate). For example, in a case where an alloy of Al and silicon is used as the base layer of a p-type crystalline silicon substrate, since the base layer has an extremely low contact resistance, a certain degree of flexibility is allowed for in the structure of the base side in accordance with the desired performance and costs. If no passivation layer is used, a back surface field (BSF) solar cell is produced in which the entire back surface of the crystalline silicon substrate is applied with an Al paste reacting with silicon, and which is inexpensive. Alternatively, a local BSF may be formed in the following manner: the back surface of the crystalline silicon substrate is terminated with a passivation film composed of AlOₓ, silicon oxide, silicon nitride, or a laminated structure thereof; openings are locally formed in the passivation layer using a laser or the like; and an Al paste is printed and baked, thereby locally alloying Al with silicon in the openings. In this case, the so-called passivated emitter and rear cell (PERC) is produced. The PERC has enhanced performance as compared with a solar cell having the BSF on its entire surface. In the case of the heterojunction mode, since the surface of the crystalline silicon substrate serves as the base of the emitter layer, a passivation layer is interposed between the surface of the crystalline silicon substrate and the emitter layer. In this case, as the passivation layer, a very thin insulating layer, a substantially intrinsic amorphous silicon layer, or a laminated structure thereof is used such that tunneling of electrical current is allowed in the vertical direction. Likewise, as a passivation layer interposed between the base layer and the crystalline silicon substrate, a very thin insulating layer, a substantially intrinsic amorphous silicon layer, or a laminated structure thereof is used.

In either of the cases of homojunction and heterojunction, an anti-reflection (AR) layer having a refractive index of about 1.7 or more and about 2.4 or less is formed on the light-receiving surface side. The AR layer is designed to have a thickness that minimizes reflectance with respect to the solar spectrum. In the case of homojunction, silicon nitride that also functions as a passivation layer is generally used as the AR layer. In the case of heterojunction, the AR layer is constituted by a transparent conductive oxide (TCO) layer, such as an indium oxide layer, that serves as a contact layer to be described later.

In the solar cell, light irradiation generates the minority carriers and the majority carriers. The minority carriers and the majority carriers are collected by the emitter layer and the base layer respectively, and thereafter, are collected by electrodes. In the case of the homojunction mode, a direct contact method is often adopted in which a silver electrode (Ag electrode) is brought into contact with the emitter layer forming part of the crystalline silicon substrate. A fire through process is employed in which: a silver paste (Ag paste) is printed on silicon nitride constituting the AR layer; the paste is baked at a high temperature of 700° C. or higher and 900° C. or lower; and at the time of baking, the silver (Ag) passes through the silicon nitride to come into direct contact with the emitter layer located below. Since metal atoms as strong recombination centers have influence in a crystalline silicon substrate, recombination at contact points (contact recombination) is strengthened. This influence can be shielded to a certain extent by reducing the diffusion length of carriers by way of doping the emitter layer. The doping exerts this effect of shielding the contact recombination more strongly as the doping concentration increases. The contact resistance between Ag and the emitter layer also decreases with an increase in the doping concentration. Thus, the output can be enhanced. On the other hand, since an excessively high doping concentration leads to an increase in recombination deriving from the dopants, the doping concentration is balanced such that the emitter layer has a sheet resistance of 100 Ω/sq or higher and 150 Ω/sq or lower. To achieve higher efficiency beyond this balance, a selective emitter method is used in which the doping concentration is locally increased only in a contact region where an electrode of the light-receiving surface side is arranged. This method contributes to a further increase in the output. In the case of heterojunction, an amorphous silicon layer is used which has a thickness of about 5 nm or more and about 20 nm or less, and thus, is thinner than the emitter layer constituted by the diffusion layer having a thickness of several micrometers. Therefore, if the direct contact method is used, a metal passes through the emitter layer and reaches the passivation layer and the crystalline silicon substrate that are provided below the emitter layer. Consequently, it is impossible to obtain the above-mentioned shielding effect by doping, and the performance is reduced significantly. For this reason, the contact layer made of the TCO is generally used to prevent direct contact of the metal. As the TCO, an indium oxide, such as ITO is used. The TCO layer functions not only as a mere contact layer, but also as an in-plane transport layer that transports the minority carriers collected by the emitter layer to a light-receiving surface electrode having a grid shape. In addition, the TCO layer also functions as the AR layer. Thus, the contact layer preferably has a thickness of 70 nm or more and 100 nm or less. The TCO layer preferably has a sheet resistance of about 30 Ω/sq or higher and about 120 Ω/sq or lower.

The metal electrode layer 21 is formed on the light-receiving surface side of the solar cell substrate 10, and the metal electrode layer 31 is formed on the back surface side of the solar cell substrate 10. The metal electrode layer 21 has the so-called comb shape, and includes a plurality of finger electrode portions 21f corresponding to the teeth of the comb, and one or more bus bar electrode portions 21b corresponding to the support of the comb teeth. The bus bar electrode portion 21b extends in the Y direction along the overlapping region Ro located in a part of the light-receiving surface side (one major surface), the part being located in an end portion in the X direction. The finger electrode portions 21f extend in the X direction transverse to the Y direction, from the bus bar electrode portion 21b. Likewise, the metal electrode layer 31 has the comb shape, and includes a plurality of finger electrode portions 31f corresponding to the teeth of the comb, and one or more bus bar electrode portions 31b corresponding to the support of the comb teeth. The bus bar electrode portion 31b extends in the Y direction along the overlapping region Ro located in a part of the back surface side, the part being located in the other end portion in the X direction. The finger electrode portions 31f extend in the X direction transverse to the Y direction, from the bus bar electrode portion 31b. Note that the metal electrode layer 31 is not limited to the comb shape. For example, in the case of using an inexpensive Al paste, the metal electrode layer 31 may be formed in a rectangular shape over substantially the entire back surface of the solar cell 2.

To reduce electric resistance while increasing the amount of incident light, the metal electrode layers 21, 31 are required to be optimally designed. From the viewpoint of increasing the output, the metal electrode layers 21, 31 are preferably configured as a high aspect ratio electrode having a small width in the X or Y direction and a large height (thickness) in a direction transverse to the X-Y plane. In the case of the homojunction mode in which high-temperature processing can be performed, a high conductivity is achieved because of progress of sintering of the Ag paste, and the metal electrode layers can be narrowed to the from about 30 μm or more and about 40 μm or less. In the case of the heterojunction mode, a high temperature of 250° C. or higher causes hydrogen desorption that deteriorates the function of the passivation layer. Accordingly, the Ag paste electrode is baked at a low temperature, and the conductivity is about one-half of that of the homojunction mode. For this reason, it is necessary to form wiring having a relatively large width of about 60 μm or more and about 100 μm or less.

As shown in FIG. 5, the bus bar electrode portion 21b on the light-receiving surface side and the bus bar electrode portion 31b on the back surface side are arranged apart from each other, in the respective opposite end portions of the solar cell 2. With this arrangement, the solar cell device 1 is achieved in which a current flows in one direction, i.e., in the X direction. As shown in FIG. 6, the finger electrode portion 31f on the back surface side is absent from a location corresponding to the overlapping region Ro of the light-receiving surface side, that is, it is slightly shorter than the finger electrode portion 21f on the light-receiving surface side. This is because the overlapping region Ro on the light-receiving surface side is an area shielded from light and receives a very small amount of incident light. Thus, a small current is generated there, and the voltage drop loss due to series resistance is negligible. On the other hand, the finger electrode portion 21f on the light-receiving surface side is arranged at a location corresponding to the overlapping region Ro of the back surface side. This is because at the location on the light-receiving surface side corresponding to the overlapping region Ro on the back surface side, a large amount of incident light is received and a large current is generated, and therefore, resistance needs to be reduced to a low value.

Each of the metal electrode layers 21, 31 is made of a metal material. From the viewpoint of an oxidization blackening processing to be described later, Ag (silver), Cu (copper), or an alloy thereof is used as the metal material.

(Details of Solar Cell Device)

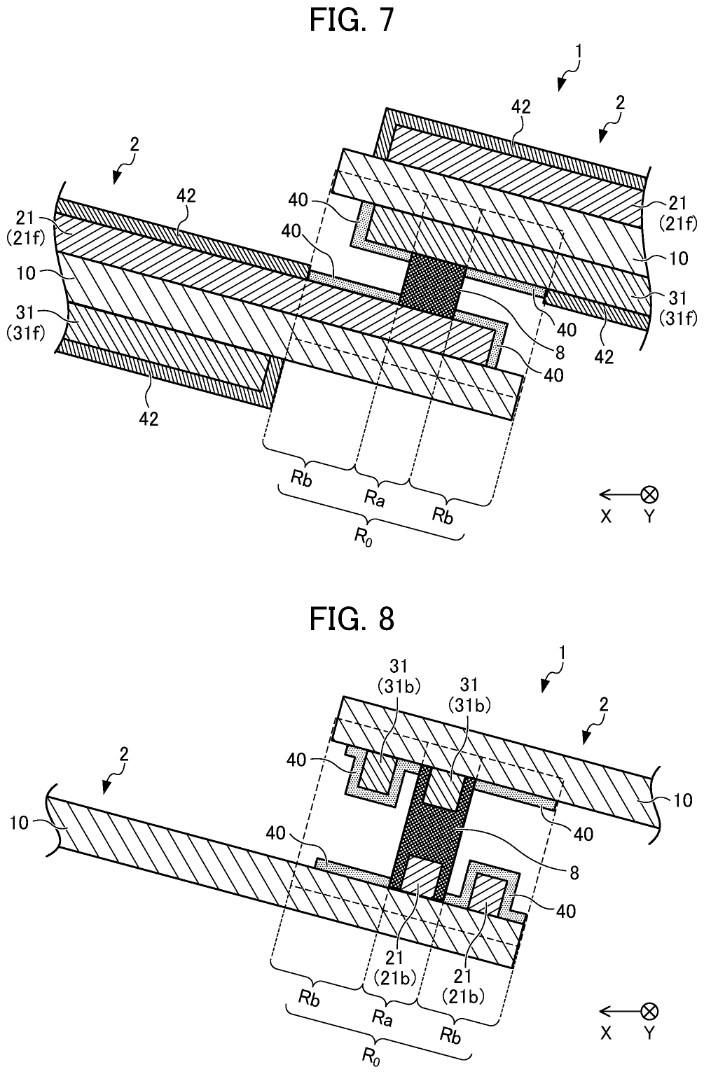

FIG. 7 shows an enlarged view of the overlapping region Ro and a vicinity thereof in the cross section taken along line II-II in FIG. 1. FIG. 8 shows an enlarged view of the overlapping region Ro and a vicinity thereof in the cross section taken along line VIII-VIII in FIG. 1. In the overlapping region Ro of the solar cells 2, a region in contact with the connection member 8 is referred to as a connection region Ra, and a region surrounding the connection region Ra is referred to as a surrounding region Rb. (In other words, the surrounding region Rb corresponds to a region resulting from exclusion of the connection region Ra from the overlapping region Ro.) The surrounding region Rb is constituted by a range from about 200 μm or more to about 1000 μm or less from the connection region Ra.

On the light-receiving surface side of the solar cell 2, the surface of the metal electrode layer 21 (21f) that is located outside the overlapping region Ro is covered with an oxide film 42. On the back surface side of the solar cell 2, the surface of the metal electrode layer 31 (31f) that is located outside the overlapping region Ro is also covered with an oxide film 42. From the viewpoint of the design characteristics of the light-receiving surface side, it is suitable that outside the overlapping region Ro of the light-receiving surface side of the solar cell 2, the oxide film 42 covers the surface of the metal electrode layer located on at least the light-receiving surface side (one major surface side).

On the other hand, on the light-receiving surface side of the solar cell 2, the surface of the metal electrode layer 21 (21f and 21b) that is located in the overlapping region Ro is covered with a barrier film (oxidation resistant film) 40, and not with the oxide film 42. Also, on the back surface side of the solar cell 2, the surface of the metal electrode layer 31 (31f and 31b) that is located in the overlapping region Ro is covered with a barrier film (oxidation resistant film) 40, and not with the oxide film 42. In other words, on the light-receiving surface side of the solar cell 2, the surface of the metal electrode layer 21 (21f and 21b) that is located in the connection region Ra and the surface of the metal electrode layer 21 (21f and 21b) that is located in the surrounding region Rb are covered with the barrier film (oxidation resistant film) 40, and not with the oxide film 42. On the back surface side of the solar cell 2, the surface of the metal electrode layer 31 (31f and 31b) that is located in the connection region Ra and the surface of the metal electrode layer 31 (31f and 31b) that is located in the surrounding region Rb are covered with the barrier film (oxidation resistant film) 40, and not with the oxide film 42. Note that it is suitable that at least a portion of the surface of the metal electrode layer 21 (21f and 21b) in the surrounding region Rb on the light-receiving surface side of the solar cell 2 be covered with the barrier film (oxidation resistant film) 40, and not with the oxide film 42. It is also suitable that at least a portion of the surface of the metal electrode layer 31 (31f and 31b) in the surrounding region Rb on the back surface side of the solar cell 2 be covered with the barrier film (oxidation resistant film) 40, and not with the oxide film 42.

The barrier film (oxidation resistant film) 40 prevents oxidation of the metal electrode layers 21, 31. Preferably, the barrier film 40 does not inhibit contact between the connection member 8 and the metal electrode layers 21, 31 in the connection region Ra, or adherence between the sealing material 5 and the metal electrode layers 21, 31 in the surrounding region Rb. Examples of the barrier film 40 include an ester-based organic film and a hydrocarbon-based organic film, both of which can be formed as a thin film on the surface of the metal electrode layers 21, 31. These organic films are constituted by low molecular weight substances that are generally known as organic pollutants in clean rooms, but satisfactorily function as a barrier film against oxidation.

The oxide film 42 is formed by way of oxidization of the surface of the metal electrode layers 21, 31, and is not a film of silicon oxide or the like produced on the metal electrode layers 21, 31. The glossy surface of the metal electrode layers 21, 31 forms a lusterless metal oxide layer when it is oxidized. In more detail, when oxidized, the surface of the metal electrode layers 21, 31 containing Ag or Cu forms the oxide film 42 containing silver oxide or copper oxide and is blackened.

(Method for Manufacturing Solar Cell Device)

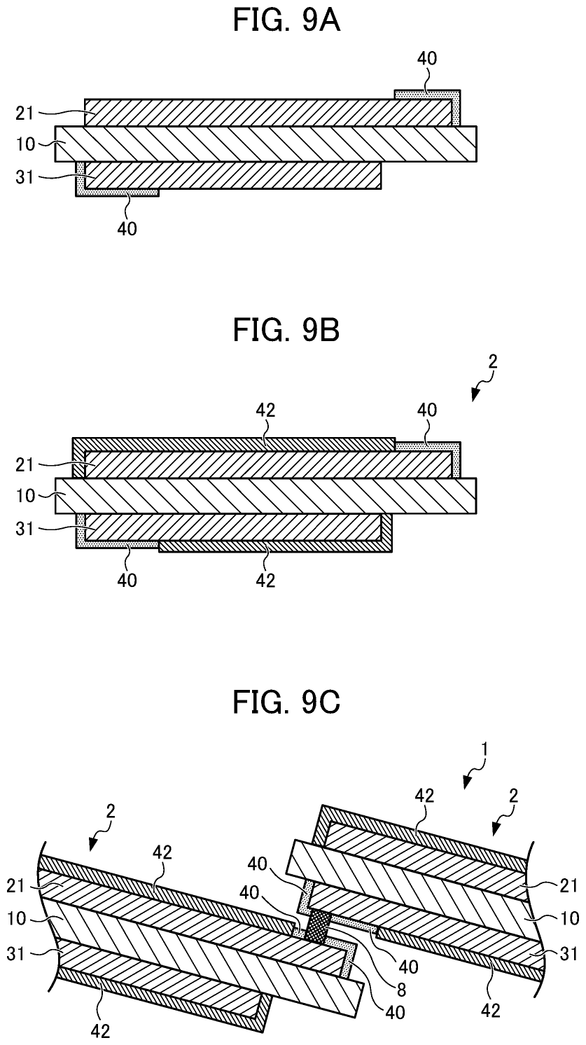

Next, a method for manufacturing the solar cell device according to the first embodiment will be described with reference to FIGS. 9A to 9C. FIG. 9A is a diagram (cross-sectional view) showing a barrier film forming step included in the method for manufacturing the solar cell device according to the first embodiment. FIG. 9B is a diagram (cross-sectional view) showing an oxide film forming step included in the method for manufacturing the solar cell device according to the first embodiment. FIG. 9C is a diagram (cross-sectional view) showing a connecting and baking step included in the method for manufacturing the solar cell device according to the first embodiment.

First, a metal electrode layer 21 is formed on the light-receiving surface side (one major surface side) of a solar cell substrate 10 having a pn junction. At this time, bus bar electrode portion 21b is formed to extend in the Y direction along an overlapping region Ro that is located in a part of one end portion in the X direction. Further, finger electrode portions 21f are formed to extend in the X direction. In addition, a metal electrode layer 31 is formed on the back surface side (the other major surface side) of the solar cell substrate 10. At this time, bus bar electrode portion 31b is formed to extend in the Y direction along an overlapping region Ro that is located in a part of the other end portion in the X direction. Further, finger electrode portions 31f are formed to extend in the X direction.

Next, as shown in FIG. 9A, a barrier film 40 is formed on (at least a portion of) the surface of the metal electrode layer 21 located in the overlapping region Ro on the light-receiving surface side of the solar cell substrate 10. Further, a barrier film 40 is formed on (at least a portion of) the surface of the metal electrode layer 31 located in the overlapping region Ro on the back surface side of the solar cell substrate 10 (the barrier film forming step). The barrier film may be the above-described ester-based or hydrocarbon-based organic layer formed by a mask deposition method, or an organic film formed by way of, for example, imprinting of a urethane foam containing the above-described ester-based or hydrocarbon-based material.

Next, as shown in FIG. 9B, the metal electrode layers 21, 31 are exposed to an oxidative atmosphere, whereby an oxide film 42 is formed on a portion of the surface of the metal electrode layers, the portion being free of the barrier film 40 (the oxide film forming step). Examples of gas contained in the oxidative atmosphere include ozone gas and the like. UV irradiation or heating may be performed to promote the oxidation reaction.

Next, as shown in FIG. 9C, the solar cells 2 are arranged to overlap with each other in the overlapping region Ro while having a connection member 8 interposed therebetween. The solar cells 2 are then subjected to baking (the connecting and baking step). At this time, the connection member 8 may be positioned on the barrier film 40 on the light-receiving surface side of one of the solar cells 2, or on the barrier film 40 on the back surface side of the other solar cell 2. (In the overlapping region Ro of the solar cells 2, a region occupied by the connection member 8 serves as the connection region Ra.) Since mechanical stress is generated when the connection member 8 is positioned, the connection member 8 penetrates the barrier films 40 to come into electrical contact with the metal electrode layers 21, 31.

Further, at this time, the solar cells 2 overlapping with each other are placed on a suction table 90 as shown in FIG. 10, and the back surface side (the other major surface side) of the solar cells 2 is under suction so that a connecting pressure is generated. In this state, the solar cells 2 are heated from the light-receiving surface side (one major surface side) using IR lamps or the like, thereby carrying out baking. Also when the solar cells 2 are under suction in this manner, mechanical stress is generated. Therefore, the connection members 8 penetrate the barrier films 40 to come into contact with the metal electrode layers 21, 31. In this manner, the solar cell device 1 including the solar cells 2 that are electrically and mechanically connected to each other is produced.

As described above, according to the solar cell device 1 of the first embodiment and the method for manufacturing the same, the oxide film 42 covers the surface of the metal electrode layer 21 (finger electrode portions 21f) that is located outside the overlapping region Ro on the light-receiving surface side (one major surface side) of the solar cell 2. As a result, the metal electrode layer 21 (finger electrode portions 21f) becomes inconspicuous (i.e., the entire surface turns into a color close to black) due to blackening of the oxide film 42 formed on the surface and containing silver oxide or copper oxide, thereby improving the design characteristics.

Meanwhile, as compared with a solar cell device produced by the conventional tab-wire connection method, a solar cell device produced by the string method, which has a rigid integrated structure (with little flexibility) including solar cell substrates (including silicon substrates) connected in series, has a low ability to relieve stress caused by temperature changes, and is insufficiently reliable in terms of thermal cycle. To address this, according to the solar cell device 1 of the present embodiment and the method for manufacturing the same, in an area located outside the overlapping region Ro and constituting a major portion of the solar cell 2, the metal electrode layers 21, 31 (finger electrode portions 21f, 31f) are covered with the oxide film 42. At the time of modularization, this configuration reduces strength of adherence between the metal electrode layers 21, 31 and the sealing material 5, and relieves the stress. This seems to be because the oxide film 42 provided between the metal electrode layers 21, 31 and the sealing material 5 allows slip between the metal electrode layers 21, 31 and the sealing material 5, whereby the stress generated by thermal expansion is relieved. As a result, the metal electrode layers 21, 31, which are sandwiched between the sealing material 5 and the solar cell substrate including the silicon substrate in which the stress is most likely to be generated, reduce the influence of the stress from the sealing material 5. This feature inhibits detachment of the metal electrode layers 21, 31, or connection failure between the metal electrode layers 21, 31, thereby improving the reliability in terms of thermal cycle.

According to the solar cell device 1 of the present embodiment and the method for manufacturing the same, in the connection region Ra that is included in the overlapping region Ro of the solar cell 2 and is in contact with the connection member 8, the surface of the metal electrode layers 21, 31 is not covered with the oxide film 42. Therefore, electrical contact resistance between the connection member 8 and the metal electrode layers 21, 31 is inhibited from increasing, whereby the output of the solar cell device 1 is inhibited from decreasing. In other words, the electrical contact resistance between the connection member 8 and the metal electrode layers 21, 31 is maintained low, and the output of the solar cell device 1 is sustained, thereby increasing the reliability.

According to the solar cell device 1 of the present embodiment and the method for manufacturing the same, in the surrounding region Rb that surrounds the connection region Ra in the overlapping region Ro of the solar cell 2, the surface of the metal electrode layers 21, 31 is not covered with the oxide film 42. Consequently, at the time of modularization, a high strength of adherence between the metal electrode layers 21, 31 and the sealing material 5 is ensured. As a result, the reliability increases in terms of thermal cycle and in terms of moisture resistance and heat resistance. In the connection region Ra of the overlapping region Ro, the metal electrode layers 21, 31 of the solar cells 2 sandwich therebetween the connection member 8, whereas in the surrounding region Rb surrounding the connection region Ra, a gap is present which is filled with the sealing material 5. Since the oxide film 42 is absent from the surrounding region Rb, the sealing material 5 with which the gap is filled is allowed to adhere to the metal electrode layers 21, 31 with an increased strength, so that the adherence in the overlapping region Ro is enhanced. This seems to prevent disconnection in the overlapping region Ro which can be caused by stress due to thermal expansion. For the reliability in terms of moisture resistance and heat resistance, it is presumed that the adherence between the metal electrode layers 21, 31 and the sealing material 5 in the surrounding region Rb can prevent infiltration of water into the connection region Ra, the infiltration leading to an increase in series resistance, whereby the reliability is improved.

### Second Embodiment

According to the manufacturing method of the solar cell device of the first embodiment, a film is produced to function as the barrier film. According to a method for manufacturing a solar cell device of a second embodiment, a barrier film is formed by way of printing and baking of a connection member paste containing the barrier film material.

(Method for Manufacturing Solar Cell Device)

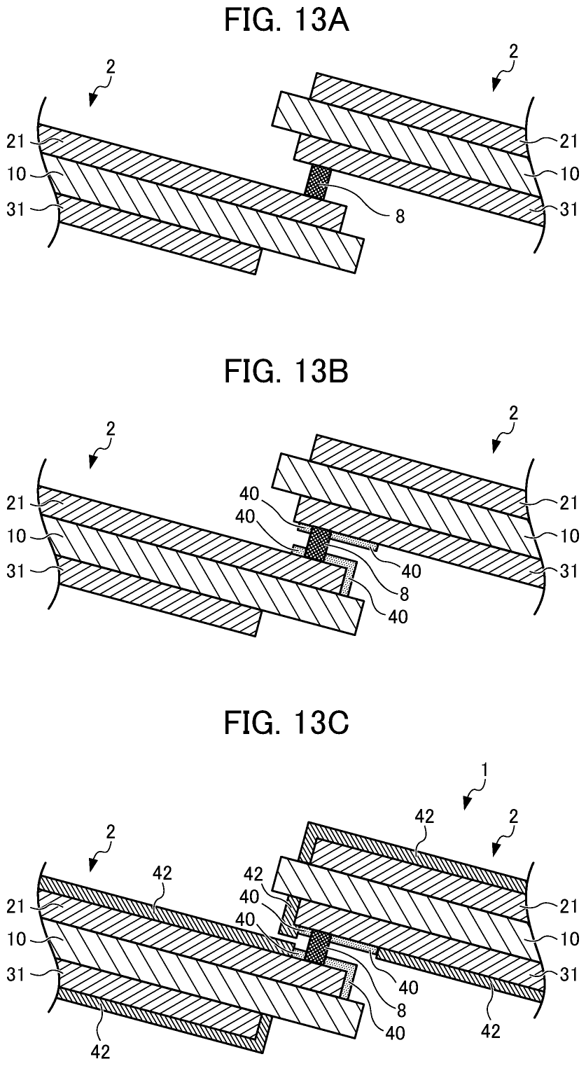

The method for manufacturing the solar cell device according to the second embodiment will be described next with reference to FIGS. 13A to 13C. FIG. 13A is a diagram (cross-sectional view) showing a connecting step included in the method for manufacturing the solar cell device according to the second embodiment. FIG. 13B is a diagram (cross-sectional view) showing a baking and barrier film forming step included in the method for manufacturing the solar cell device according to the second embodiment. FIG. 13C is a diagram (cross-sectional view) showing an oxide film forming step included in the method for manufacturing the solar cell device according to the second embodiment.

First, a metal electrode layer 21 is formed on a light-receiving surface side (one major surface side) of a solar cell substrate 10 having a pn junction. At this time, bus bar electrode portion 21b is formed to extend in a Y direction along an overlapping region Ro that is located in a part of one end portion in the X direction. Further, finger electrode portions 21f are formed to extend in the X direction. In addition, a metal electrode layer 31 is formed on the back surface side (the other major surface side) of the solar cell substrate 10. At this time, bus bar electrode portion 31b is formed to extend in the Y direction along an overlapping region Ro that is located in a part of the other end portion in the X direction. Further, finger electrode portions 31f are formed to extend in the X direction.

Next, as shown in FIG. 13A, the solar cells 2 are arranged to overlap with each other in the overlapping region Ro while having a connection member 8 interposed therebetween (the connecting step). As the connection member 8 of the second embodiment, a connection member paste is used which includes, for example, a conductive adhesive paste composed of an adhesive thermosetting resin material, conductive particles (e.g., fine metal particles) dispersed in the resin material, and a barrier film material. Examples of the connection member 8 include a Ag or Cu paste containing an oligomer component such as urethane acrylate. The connection member 8 is formed by, for example, a forming method in which the connection member paste is applied to or printed on a connection region Ra in the overlapping region Ro. At this time, the connection member may be applied to the connection region Ra on the light-receiving surface side of one solar cell 2 or to the connection region Ra on the back surface side of the other solar cell 2.

Next, as shown in FIG. 13B, the solar cells 2 overlapping with each other with the connection member 8 interposed therebetween are baked. At this time, as in the first embodiment, while the back surface side (the other major surface side) of the solar cells 2 is under suction so that a connecting pressure is generated, the solar cells 2 are heated from the light-receiving surface side (one major surface side) using IR lamps or the like, as shown in FIG. 10. In this manner, the solar cells 2 are electrically and mechanically connected to each other. Further, at this time, a low molecular weight component bleeding or evaporating from the connection member paste adheres to the surrounding region Rb and thereby forms barrier films 40 (the baking and barrier film forming step).

Next, as shown in FIG. 13C, the metal electrode layers 21, 31 are exposed to an oxidative atmosphere, whereby oxide films 42 are formed on a portion of the surface of the metal electrode layers 21, 31, the portion being free of the barrier film 40 and the connection member 8 (the oxide film forming step). In this manner, the solar cell device 1 is manufactured.

(Solar Cell Device)

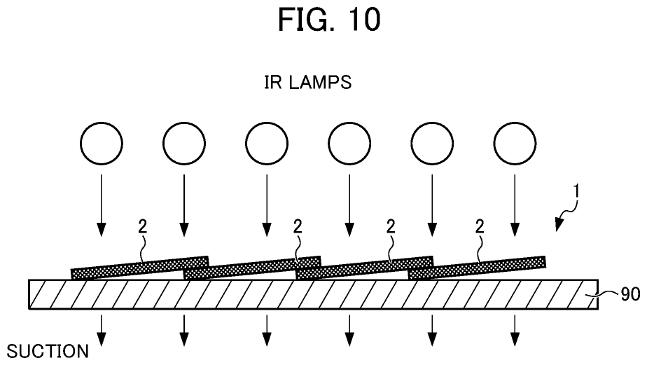

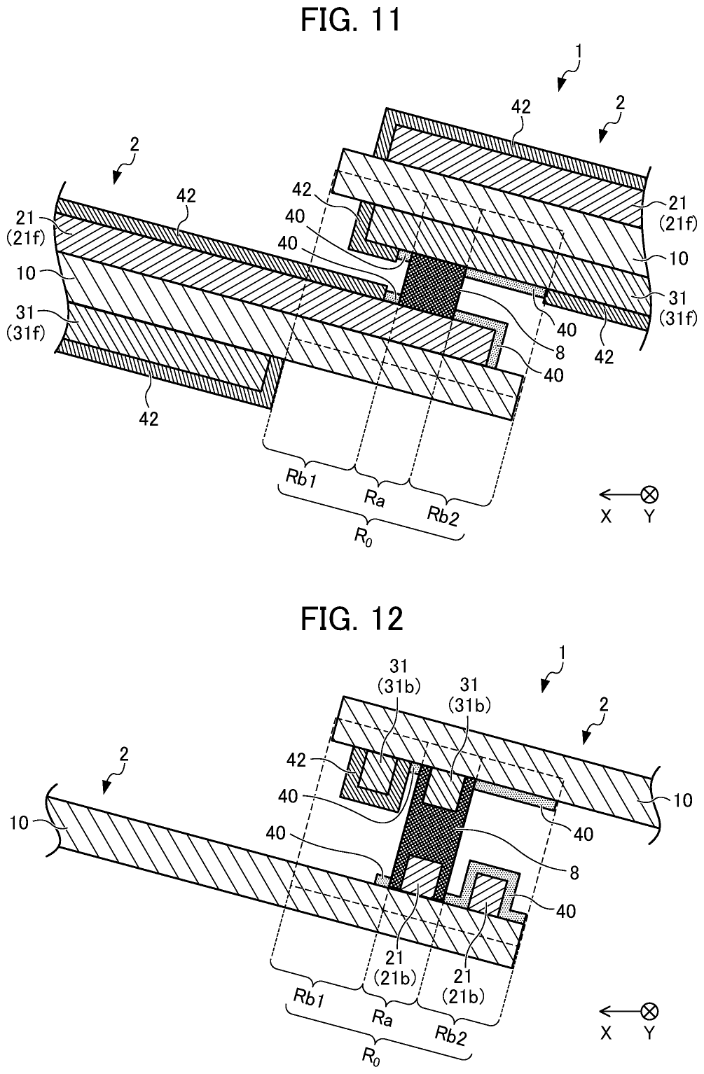

FIG. 11 shows an enlarged view of the overlapping region and a vicinity thereof of the solar cell device according to the second embodiment, in a cross section taken along line II-II in FIG. 1. FIG. 12 shows an enlarged view of the overlapping region and a vicinity thereof of the solar cell device according to the second embodiment, in the cross section taken along line VIII-VIII in FIG. 1.

As described earlier, the solar cell device 1 according to the second embodiment differs from the solar cell device of the first embodiment in that: since the barrier film 40 is formed by printing and baking the connection member paste containing the barrier film material, the barrier film (oxidation resistant film) 40 is not formed on the surface of the metal electrode layer 21 (21f and 21b) located in the connection region Ra on the light-receiving surface side of the solar cell 2, or on the surface of the metal electrode layer 31 (31f and 31b) located in the connection region Ra on the back surface side of the solar cell 2 (see, FIGS. 9A and 9B). Note that the solar cell device 1 of the second embodiment and that of the first embodiment share the same configuration in which the oxide film 42 does not cover the surface of the metal electrode layer 21 (21f and 21b) located in the connection region Ra on the light-receiving surface side of the solar cell 2, and the surface of the metal electrode layer 31 (31f and 31b) located in the connection region Ra on the back surface side of the solar cell 2.

Here, a direction in which the solar cells 2 are aligned is defined as the alignment direction (X direction) and a direction transverse to the alignment direction is defined as the transverse direction (Y direction). In the overlapping region Ro of the solar cell 2, a side close to an end of the solar cell 2 that is positioned under, and overlaid by, the adjacent solar cell 2 is referred to as the shielded side, and a side opposite to the shielded side in the alignment direction is referred to as the exposed side. As described earlier, when the barrier film 40 is formed by printing and baking the connection member paste containing the barrier film material, the back surface side (the other major surface side) of the solar cells 2 is placed under suction such that connecting pressure is generated, as shown in FIG. 10. Consequently, the barrier film 40 formed by way of bleeding or evaporation of the connection member paste has an imbalance from the exposed side to the shielded side. As a result, in the overlapping region Ro of the solar cell 2, a coverage of the metal electrode layer 21 by the oxide film 42 in a surrounding region Rb1 located toward the exposed side with respect to the connection member 8 is asymmetrical to a coverage of the metal electrode layer 21 by the oxide film 42 in a surrounding region Rb2 located toward the shielded side with respect to the connection member 8.

In more detail, in the overlapping region Ro of the solar cell 2, the coverage of the metal electrode layer 21 by the oxide film 42 in the surrounding region Rb1 located toward the exposed side with respect to the connection member 8 is higher than the coverage of the metal electrode layer 21 by the oxide film 42 in the surrounding region Rb2 located toward the shielded side with respect to the connection member 8.

When the barrier film 40 is formed by way of printing and baking of the connection member paste containing the barrier film material, the light-receiving surface side (one major surface side) of the solar cells may be under suction. In this case, in the overlapping region Ro of the solar cell 2, a coverage of the metal electrode layer 21 by the oxide film 42 in the surrounding region Rb1 located toward the exposed side with respect to the connection member 8 becomes lower than a coverage of the metal electrode layer 21 by the oxide film 42 in the surrounding region Rb2 located toward the shielded side with respect to the connection member 8. In this case, from the viewpoint of the design characteristics, it is preferable that the oxide film 42 be not formed outside the overlapping region Ro of the solar cell 2.

The solar cell device 1 according to the second embodiment and the method for manufacturing the same exert the same effects as those of the solar cell device 1 according to the first embodiment and the method for manufacturing the same.

(Modification)

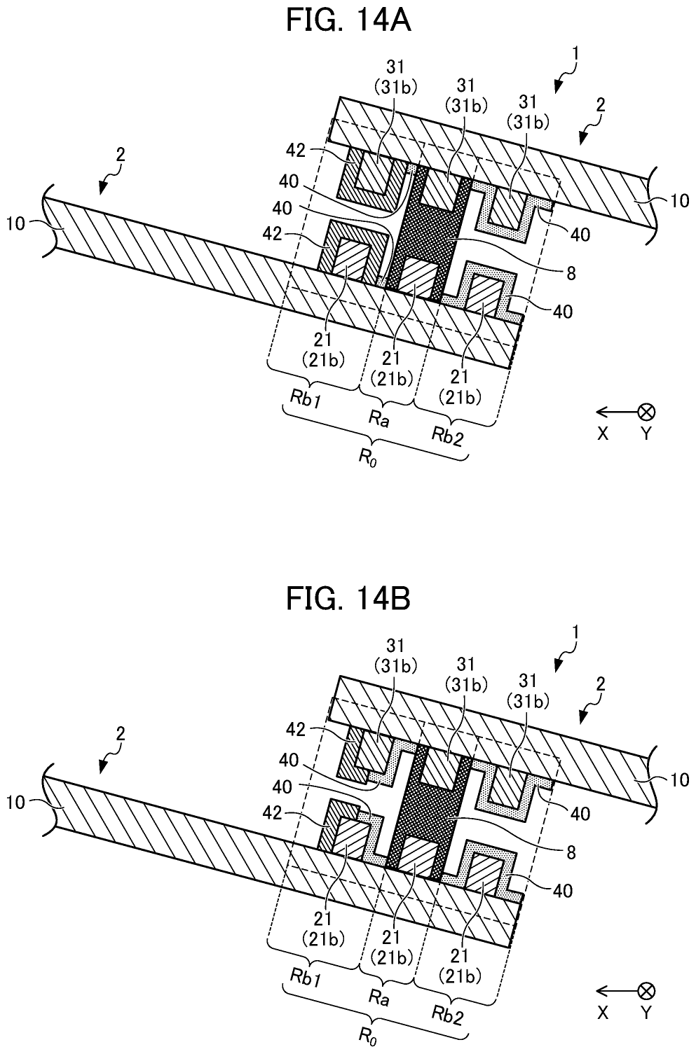

FIGS. 14A and 14B each show an enlarged view of an overlapping region and a vicinity thereof in a cross section of a solar cell device according to a modification of the second embodiment, the cross section corresponding to the cross section taken along line VIII-VIII in FIG. 1. As shown in FIG. 14A, in a case where the overlapping region Ro of the solar cell 2 includes a plurality of metal electrode layers 21 (bus bar electrode portions 21b and 31b) extending in the Y direction (transverse direction), the metal electrode layers 21, 31 located closest to the light-receiving side may be covered with the oxide film 42. Alternatively, at least a portion of each of the metal electrode layers 21, 31 located closest to the exposed side may be covered with the oxide film 42.

The embodiments of the present invention have been described in the foregoing. However, the present invention is not limited to the embodiments described above, and various changes and modifications can be made to the present invention. For example, in the above-described embodiments, the metal electrode layer 21 on the light-receiving surface side of the solar cell 2 and the metal electrode layer 31 on the back surface side of the solar cell 2 are made of the same material. However, the present invention is not limited thereto. The metal electrode layer 21 on the light-receiving surface side and the metal electrode layer 31 on the back surface side may be made of different materials. For example, from the viewpoint of the design characteristics, the metal electrode layer 21 on the light-receiving surface side may be made of Ag, Cu, or the like that can be blackened by oxidation, and from the viewpoint of costs, the metal electrode layer 31 on the back surface side may be made of Al or the like. Further, on the light-receiving surface side, the metal electrode layer 21 formed in the overlapping region Ro and the metal electrode layer 21 formed outside the overlapping region Ro may be made of different materials. For example, from the viewpoint of the design characteristics, the metal electrode layer 21 outside the overlapping region Ro on the light-receiving surface side may be made of Ag, Cu, or the like that can be blackened by oxidation, whereas the metal electrode layer 21 in the overlapping region Ro on the light-receiving surface side may be made of a material other than Ag and Cu. That is, according to the present invention, at least on the light-receiving surface side (one major surface side), it is suitable that the surface of the metal electrode layer located outside the overlapping region Ro of the solar cell 2 be covered by the oxide film.

### EXAMPLES

The present invention will be specifically described with reference to examples. It should be noted that the present invention is not limited to the following examples.

### Example 1

As will be described below, the solar cell device 1 according to the first embodiment shown in FIGS. 1, 2, 7, and 8 was fabricated by the manufacturing method according to the first embodiment shown in FIGS. 9A to 9C. A solar cell module 100 including the solar cell device 1 according to the first embodiment was produced as Example 1. First, the metal electrode layer 21 (the bus bar electrode portion 21b and the finger electrode portions 21f) was formed on the light-receiving surface side (one major surface side) of the solar cell substrate 10 having a pn junction. The metal electrode layer 31 (the bus bar electrode portion 31b and the finger electrode portions 31f) was formed on the back surface side (the other major surface side) of the solar cell substrate 10.

Next, as shown in FIG. 9A, the barrier film 40 is formed on (at least a portion of) the surface of the metal electrode layer 21 located in the overlapping region Ro on the light-receiving surface side of the solar cell substrate 10, and the barrier film 40 is formed on (at least a portion of) the surface of the metal electrode layer 31 located in the overlapping region Ro on the back surface side of the solar cell substrate 10 (the barrier film forming step). As the barrier film, the above-described hydrocarbon-based organic film was formed by a mask deposition method.

Next, as shown in FIG. 9B, the metal electrode layers were exposed to an oxidative atmosphere, so that the oxide film 42 was formed on a portion of the surface of the metal electrode layers, the portion being free of the barrier film (the oxide film forming step).

Next, as shown in FIG. 9C, the solar cells 2 were arranged to overlap with each other in the overlapping region Ro while having the connection member 8 interposed therebetween. The solar cells 2 were then subjected to baking (the connecting and baking step). At this time, while the back surface side (the other major surface side) of the solar cells 2 was under suction to generate a connecting pressure, the solar cells 2 were heated from the light-receiving surface side (one major surface side) using IR lamps, thereby carrying out baking. In this manner, the solar cell device 1 including the solar cells 2 that were electrically and mechanically connected to each other was produced.

Thereafter, the solar cell device 1 was sandwiched between ethylene-vinyl acetate (EVA) sheets as the sealing material 5, and then sandwiched between tempered glass substrates as the light-receiving side protective member 3 and the backside protective member 4 so as to be formed into a lamination structure. In this manner, the solar cell module 100 was produced.

In Example 1, since the oxide film 42 was formed on the surface of the metal electrode layers 21, 31 located outside the overlapping region Ro on the light-receiving surface, the metal electrode layers 21, 31 on the light-receiving surface were not visually recognized after the implementation of sealing, thereby exhibiting excellent design characteristics.

### Example 2

As will be described below, the solar cell device 1 according to the second embodiment shown in FIGS. 1, 2, 11, and 12 was fabricated by the manufacturing method according to the second embodiment shown in FIGS. 13A to 13C. A solar cell module 100 including the solar cell device 1 according to the second embodiment was produced as Example 2. First, as in Example 1, the metal electrode layer 21 (the bus bar electrode portion 21b and the finger electrode portions 21f) was formed on the light-receiving surface side (one major surface side) of the solar cell substrate 10 having a pn junction. The metal electrode layer 31 (the bus bar electrode portion 31b and the finger electrode portions 31f) was formed on the back surface side (the other major surface side) of the solar cell substrate 10.

Next, as shown in FIG. 13A, the solar cells 2 were arranged to overlap with each other in the overlapping region Ro while having the connection members 8 interposed therebetween (the connecting step). At this time, a Ag paste containing an oligomer component of urethane acrylate was applied to or printed on the connection region Ra in the overlapping region Ro.

Next, as shown in FIG. 13B, the solar cells 2 overlapping with each other with the connection member 8 interposed therebetween were subjected to baking. At this time, as in Example 1, while the back surface side (the other major surface side) of the solar cells 2 was under suction to generate a connecting pressure, the solar cells 2 were heated from the light-receiving surface side (one major surface side) using IR lamps, as shown in FIG. 10. In this manner, the solar cells 2 were electrically and mechanically connected to each other. Further, at this time, a low molecular weight component bleeding or evaporating from the connection member paste adhered to the surrounding region and thereby formed the barrier film 40 (the baking and barrier film forming step).

Next, the metal electrode layers 21, 31 were exposed to an oxidative atmosphere, so that the oxide film 42 was formed on a portion of the surface of the metal electrode layers 21, 31, the portion being free of the barrier film 40 and the connection member 8 (the oxide film forming step). In this manner, the solar cell device 1 was produced.

Thereafter, as in Example 1, the solar cell device 1 was sandwiched between ethylene-vinyl acetate (EVA) sheets as the sealing material 5, and then sandwiched between tempered glass substrates as the light-receiving side protective member 3 and the backside protective member 4 so as to be formed into a lamination structure. In this manner, the solar cell module 100 was produced.

Also in Example 2, since the oxide film 42 was formed on the surface of the metal electrode layers 21, 31 located outside the overlapping region Ro on the light-receiving surface, the metal electrode layers 21, 31 on the light-receiving surface were not visually recognized after the implementation of sealing, thereby exhibiting excellent design characteristics. In Example 2, a coverage of the metal electrode layer by the oxide film 42 in the surrounding region Rb1 close to the light-receiving side of the solar cell 2 is higher than a coverage in the surrounding region Rb2 close to the shielded side.

### Comparative Example 1

As Comparative Example 1, a solar cell module was produced in which no barrier film was formed and oxide films covered the entire surface of metal electrode layers on the light-receiving surface side and the back surface side. Comparative Example 1 was produced by a method corresponding to the method of Example 1, but excluding the barrier film forming step shown in FIG. 9A.

Comparative Example 1 included, in the connection region of the overlapping region, an oxide film formed between the connection member and the metal electrode layer on the light-receiving surface side and an oxide film formed between the connection member and the metal electrode layer on the back surface side. The presence of the oxide films resulted in a high contact resistance. The high contact resistance was reflected to the series resistance of the whole module, so that the initial output was lower than that of Examples 1 and 2 by about 3.5%. Also in Comparative Example 1, since an oxide film was formed on the surface of the metal electrode layer located outside the overlapping region on the light-receiving surface, the metal electrode layer on the light-receiving surface was not visually recognized after the implementation of sealing, thereby exhibiting excellent design characteristics.

### Comparative Example 2

As Comparative Example 2, a structure was produced in which no barrier film was formed, and formation of an oxide film was inhibited by a connection member covering only a connection region. Comparative Example 2 was produced by a method corresponding to the method of Example 2, but using, as the connection member paste, a Ag paste including an epoxy-based binder with a small amount of a low molecular weight component, instead of the Ag paste including the oligomer component such as urethane acrylate. As a result, no barrier film 40 was formed at the connecting and baking step shown in FIG. 13B, while an oxide film was formed not only outside the overlapping region, but also in the surrounding region at the oxide film forming step. That is, the metal electrode layer on the light-receiving surface side and that on the back surface side were entirely covered with the black oxide film, except for the connection region.

In Comparative Example 2, since the connection member is in satisfactory contact with the metal electrode layers on the light-receiving surface side and the back surface side, the initial output properties were equivalent to those of Examples 1 and 2. Also in Comparative Example 2, since the oxide film was formed on the surface of the metal electrode layer located outside the overlapping region on the light-receiving surface, the metal electrode layer on the light-receiving surface was not visually recognized after the implementation of sealing, thereby exhibiting excellent design characteristics.

### Comparative Example 3

As Comparative Example 3, a solar cell module was produced which included solar cells having no barrier film and no oxide film formed thereon. Comparative Example 3 was produced by a method corresponding to the method of Example 2, but excluding the oxide film forming step.

In Comparative Example 3, due to an effect by which light reflected by the metal electrode layer on the light-receiving surface side was confined within the module, the current was slightly increased, whereby the initial output properties were higher than those of Examples 1 and 2 by about 0.8%. However, since no oxide film was formed on the surface of the metal electrode layer located outside the overlapping region, the metal electrode layer on the light-receiving surface side was visually recognized.

The thus produced solar cell modules of Examples 1 and 2 and Comparative Examples 1 to 3 were subjected to measurement of reliability in terms of thermal cycle and reliability in terms of resistance to moist heat. To measure the reliability in terms of thermal cycle, a cycle in which the ambient temperature was changed from 80° C. to −40° C. was repeated 250 times. The reliability was evaluated based on a percentage of the output maintained with respect to the initial output after the repetition of the cycle. (Preferably, the percentage of the maintained output is 95% or more). To measure the reliability in terms resistance to moist heat, the solar cell modules were left in a state where the ambient temperature was 85° C. and the ambient humidity was 85% for 2000 hours. The reliability was evaluated based on the percentage of the output maintained with respect to the initial output after the elapse of 2000 hours. (Preferably, the percentage of the maintained output is 95% or more). In addition, the design characteristics of the solar battery modules of Examples 1 and 2 and Comparative Examples 1 to 3 were evaluated. The evaluation of the design characteristics was indicated by a cross or a circle, the cross meaning that the metal electrode layer 21 (21f) on the light-receiving surface side was visually recognized, and the circle meaning that the metal electrode layer 21 (21f) on the light-receiving surface side was hardly recognized visually and the appearance was the same or similar to a light-receiving surface provided with no electrodes. The results are shown in Table 1.

TABLE 1

| | | | | | | | Design |
|---|---|---|---|---|---|---|---|
| | Oxide Film | | | | Reliability | | Characteristics |
| | | | Outside of | | | Moisture | of Light- |
| | Connection | Surrounding | Overlapping | Barrier | Thermal | Heat | Receiving |
| | Region | Region | Region | Film | Cycle | Resistance | Surface |
| Example 1 | Absent | Absent | Present | Printing | 97.80% | 95.80% | ◯ |
| Example 2 | Absent | Absent | Present | Connection | 98.30% | 96.30% | ◯ |
| | | | | Member | | | |
| Comparative | Present | Present | Present | Absent | 94.21% | 88.60% | ◯ |
| Example 1 | | | | | | | |
| Comparative | Absent | Present | Present | Absent | 95.60% | 94.56% | ◯ |
| Example 2 | | | | | | | |
| Comparative | Absent | Absent | Absent | Absent | 95.06% | 95.22% | X |
| Example 3 | | | | | | | |

Table 1 shows that the oxide film has contributed to improvement of the design characteristics of Examples 1 and 2 and Comparative Examples 1 and 2. A comparison with Comparative Example 3 demonstrates that the excellent design characteristics were attributed to the configuration in which the black oxide films 42 cover the surface of the metal electrode layer 21 outside the overlapping region Ro on the light-receiving surface side and the surface of the metal electrode layer 31 outside the overlapping region Ro on the back surface side.

Comparative Example 1 resulted in low reliability in terms of thermal cycle and low reliability in terms of resistance to moist heat. This seems to be because the oxide film interposed in the connection region would prevent the connection member and the metal electrode layers on the light-receiving surface side and the back surface side from being in electrical and mechanical contact with each other to a suitable extent, and the electrical contact could not be maintained during the reliability test, thereby resulting in the low reliability. In addition, since the oxide film is interposed also in the surrounding region, it is presumed that poor adherence would be provided between the sealing material and the metal electrode layers on the light-receiving surface side and the back surface side, thereby making it impossible to maintain the connection and to prevent infiltration of water.

Comparative Example 2 exhibited slightly lower reliability in terms of thermal cycle than Examples 1 and 2, but the percentage of the maintained output was 95% or higher. This means that the reliability of Comparative Example 2 is high. On the other hand, the reliability in terms of resistance to moist heat was low, following Comparative Example. This seems to be because the oxide film interposed in the surrounding region would weaken the adherence between the sealing material and the metal electrode layers on the light-receiving surface side and the back surface side, thereby making it impossible to completely prevent the infiltration of water. Comparative Example 3 exhibited higher reliability in terms of resistance to moist heat than Comparative Example 2, and the percentage of the maintained output is equivalent to those of Examples 1 and 2. From this result, it is presumed that although formation of the oxide film outside the overlapping region would slightly facilitate the infiltration of water, the adherence between the sealing material and the metal electrode layers on the light-receiving side and back surface side in the surrounding region prevents further infiltration of water.

Examples 1 and 2 exhibited a particularly high percentage of the maintained output in the thermal cycle test. As described above, the high percentage maintained is attributed to the configuration in which the oxide film 42 formed outside the overlapping region Ro relieves the stress with the sealing material 5, and to the adherence between the metal electrode layers 21, 31 and the sealing material 5 in the surrounding region Rb.

It has been verified that the technique constituting Examples 1 and 2 according to the present invention achieves both excellent reliability and excellent design characteristics. A comparison between Examples 1 and 2 shows that the design characteristics of Example 2 are more excellent than those of Example 1. This is because in Example 2, the coverage by the oxide film 42 in the surrounding region Rb close to the light-receiving side is high as shown in FIGS. 11 and 12, whereby metallic lusters was less likely to remain outside the overlapping region Ro on the light-receiving side, as compared with Example 1.

### EXPLANATION OF REFERENCE CHARACTERS

1: Solar Cell Device
2: Solar Cell
3: Light-Receiving Side Protective Member
4: Backside Protective Member
5: Sealing Material
8: Connection Member
10: Solar Cell Substrate
21, 31: Metal Electrode Layer
21f, 31f: Finger Electrode Portion
21b, 31b: Bus Bar Electrode Portion
40: Barrier Film (Oxidation Resistant Film)
42: Oxide Film
100: Solar Cell Module
Ro: Overlapping Region
Ra: Connection Region
Rb, Rb1, Rb2: Surrounding Region

1. A solar cell device comprising a plurality of double-sided electrode type solar cells having both major surfaces provided with metal electrode layers, the solar cells being electrically connected to each other by a shingling method,
wherein adjacent ones of the solar cells are electrically connected to each other such that one of the adjacent solar cells overlaps with the other while having a connection member interposed therebetween,
wherein in the solar cell,
a region which is located in an end portion overlaid by the adjacent solar cell, and which is on one of the major surfaces facing the adjacent solar cell is referred to as an overlapping region,
a region which is included in the overlapping region and is in contact with the connection member is referred to as a connection region, and
a region which is included in the overlapping region and surrounds the connection region is referred to as a surrounding region,
wherein outside the overlapping region of the solar cell, a surface of the metal electrode layer on at least one major surface of the major surfaces is covered with an oxide film, and
wherein the surface of the metal electrode layer in the connection region of the solar cell and at least a portion of the surface of the metal electrode layer in the surrounding region of the solar cell are not covered with an oxide film.

2. The solar cell device according to claim 1, wherein the metal electrode layer on at least one of the major surfaces of the solar cell is made of a material containing silver or copper.

3. The solar cell device according to claim 1, wherein an oxidation resistant film is formed on the surface of the metal electrode layer in the connection region and the surrounding region of the solar cell.

4. The solar cell device according to claim 1,
wherein the connection member includes fine metal particles, and
wherein an oxidation resistant film is formed on the surface of the metal electrode layer in the surrounding region of the solar cell.

5. The solar cell device according to claim 4,
wherein a direction in which the solar cells are aligned is defined as an alignment direction,
wherein in the overlapping region of the solar cell, a side of the solar cell which is positioned under, and overlaid by, the adjacent solar cell is referred to as a shielded side, and a side opposite to the shielded side in the alignment direction is referred to as an exposed side, and
wherein in the overlapping region of the solar cell, a coverage of the metal electrode layer by the oxide film in a region toward the exposed side with respect to the connection member is asymmetric to a coverage of the metal electrode layer by the oxide film in a region toward the shielded side with respect to the connection member.

6. The solar cell device according to claim 5, wherein in the overlapping region of the solar cell, the coverage of the metal electrode layer by the oxide film in the region toward the exposed side with respect to the connection member is higher than the coverage of the metal electrode layer by the oxide film in the region toward the shielded side with respect to the connection member.

7. The solar cell device according to claim 5,
wherein a direction transverse to the alignment direction is defined as a transverse direction, and
wherein the metal electrode layer in the overlapping region comprises a plurality of metal electrode layers extending in the transverse direction, and the oxide film covers at least a portion of one of the metal electrode layers that is located closest to the exposed side.

8. A method for manufacturing a solar cell device, the solar cell device including a plurality of double-sided electrode type solar cells having both major surfaces provided with metal electrode layers, the solar cells being electrically connected to each other by a shingling method wherein in the solar cell, a region which is located in an end portion overlaid by the adjacent solar cell, and which is on one of the major surfaces facing the adjacent solar cell is referred to as an overlapping region, a region which is included in the overlapping region and is in contact with the connection member is referred to as a connection region, and a region which is included in the overlapping region and surrounds the connection region is referred to as a surrounding region, the method comprising:
forming an oxidation resistant film on a surface of the metal electrode layer in the overlapping region of the solar cell; and
forming, by way of exposure to an oxidative atmosphere, an oxide film on the surface of the metal electrode layer on at least one of the major surfaces, the surface being located outside the overlapping region of the solar cell,
wherein the forming the oxidation resistant film includes:
forming, before the connection member is arranged in the connection region of the solar cell, the oxidation resistant film on the surface of the metal electrode layer in the connection region of the solar cell and at least a portion of the surface of the metal electrode layer in the surrounding region, or
forming, after the connection member is arranged in the connection region of the solar cell, the oxidation resistant film on at least a portion of the surface of the metal electrode layer in the surrounding region.

9. The method according to claim 8, wherein the forming the oxidation resistant film includes producing a film as the oxidation resistant film before the connection member is arranged in the connection region of the solar cell.

10. The method according to claim 8, wherein the forming the oxidation resistant film includes, after the connection member including an oxidation resistant film material is arranged in the connection region of the solar cell, baking the connection member so that the oxidation resistant film material bleeding or evaporating from the connection member forms the oxidation resistant film.

11. The method according to claim 10, wherein in the forming the oxidation resistant film, the baking of the connection member is carried out while the one major surface or the other major surface of the solar cells is under suction.

12. The method according to claim 8, wherein the oxidative atmosphere in the forming of the oxide film includes ozone gas.
